(19) United States
(12) Patent Application Publication
(10) Pub. No.: US 2012/0056331 A1
(43) Pub. Date: Mar. 8, 2012

(54) METHODS OF FORMING SEMICONDUCTOR DEVICE AND SEMICONDUCTOR DEVICES FORMED BY THE SAME

(75) Inventor: Kunsik Park, Daejeon (KR)

(73) Assignee: Electronics and Telecommunications Research Institute, Daejeon (KR)

(21) Appl. No.: 13/226,421

(22) Filed: Sep. 6, 2011

(30) Foreign Application Priority Data
Sep. 6, 2010 (KR) 10-2010-0087137
Dec. 16, 2010 (KR) 10-2010-0129142

(51) Int. Cl. H01L 23/48; H01L 21/768

(52) U.S. Cl. 257/774; 438/653; 257/E21.584; 257/E23.011

(57) ABSTRACT

Provided are a method of forming a semiconductor device including a via and a semiconductor device formed by the same. In the method, by forming an unseeded layer that covers a seed layer disposed on a substrate and at a side wall of a via hole, exposes the seed layer disposed at a bottom of the via hole, and cannot serve as a seed, a plated layer configuring the via is formed upward from the seed layer in a bottom-up growth process, and thus, a void is not formed. Also, an inlet of the via hole is not blocked by using the bottom-up growth process, and thus, an electroplating speed can increase, thereby shortening a time taken in filling the via hole with a metal.

### CROSS-REFERENCE TO RELATED APPLICATIONS

This U.S. non-provisional patent application claims priority under 35 U.S.C. §119 of Korean Patent Application Nos. 10-2010-0087137, filed on Sep. 6, 2010, and 10-2010-0129142, filed on Dec. 16, 2010, the entire contents of which are hereby incorporated by reference.

### BACKGROUND OF THE INVENTION

The present invention disclosed herein relates to a method of forming a semiconductor device and a semiconductor device formed by the same.

With the lightening, thinning, shortening and miniaturizing trend of products, semiconductor devices as a type of product are required to increase in function and decrease in size. To satisfy such requirements, various technologies of packaging semiconductor devices have been and are being developed. As representative one of such package technologies, there is a Through Silicon Via (TSV) package technology that forms a TSV, passing through a semiconductor die, in a region corresponding to the bond pad of the semiconductor die and forms a through electrode by filling a metal. Such package technology shortens a connection length between a semiconductor die and a semiconductor package, and thus is attracting much attention as technology for high-performance and ultra-small semiconductor packages. In such a TSV package process, a via filling process of filling a via hole with a metal expends 25% or more of total cost, and thus, it is urgently required to secure a low-cost via filling process so as to practically use the TSV package technology. Also, in a semiconductor wiring process such as damascene, it is important to develop a via filling process that easily fills a via hole with a metal without a void being formed.

### SUMMARY OF THE INVENTION

The present invention provides a method which forms a semiconductor device including a via or a through via without a void being formed.

The present invention also provides a semiconductor device, including a via or a through via, with enhanced reliability.

Embodiments of the present invention provide a method of forming a semiconductor device including: forming a via hole in a substrate; forming a seed layer at least on a bottom and side wall of the via hole and the substrate; forming an unseeded layer which covers the seed layer disposed at the side wall of the via hole, exposes the seed layer disposed at the bottom of the via hole, and does not serve as a seed; and growing a plated layer from the exposed seed layer to fill the via hole by performing a plating process.

In some embodiments, the unseeded layer may include at least one selected from a group which includes silicon oxide, silicon nitride, silicon, titanium, titanium nitride, titanium tungsten, tungsten, tantalum, tantalum nitride, and aluminum.

In other embodiments, the seed layer and the plated layer may include copper.

In still other embodiments, the forming of an unseeded layer may use at least one selected from a group which includes a physical vapor deposition process, a plasma-enhanced chemical vapor deposition process, a sputtering process, and a spin coating process.

In even other embodiments, the forming of an unseeded layer may include: forming an unseeded layer which thickly covers the seed layer disposed at the side wall of the via hole and thinly covers the seed layer disposed at the bottom of the via hole; and removing the unseeded layer, disposed at the bottom of the via hole, to expose the seed layer.

In yet other embodiments, the plated layer may include first and second plated layers, and the forming of a via hole may include: growing the first plated layer from the seed layer to a height lower than a top of the unseeded layer; removing the unseeded layer; and growing the second plated layer from the seed layer and the first plated layer.

In further embodiments, the method may further include planarly removing the seed layer, unseeded layer and plated layer on the substrate to expose the substrate.

In still further embodiments, before the forming of a seed layer, the method may further include: forming an insulation layer conformally covering the substrate where the via hole is formed; and forming a barrier layer covering the insulation layer.

In other embodiments of the present invention, a semiconductor device includes: a substrate; a via formed in the substrate; a seed layer disposed between the substrate and the via; and an unseeded layer disposed between the seed layer and the via, and not serving as a seed.

In some embodiments, the unseeded layer may include at least one selected from a group which includes silicon oxide, silicon nitride, silicon, titanium, titanium nitride, titanium tungsten, tungsten, tantalum, tantalum nitride, and aluminum.

In still other embodiments of the present invention, a semiconductor device includes: a substrate; a via formed in the substrate; and a seed layer disposed between the substrate and the via, wherein the via includes: a first plated layer having a top which is disposed at a height lower than a top of the substrate, and not contacting a top of the seed layer; and a second plated layer disposed on the first plated layer, and contacting an upper side wall of the first plated layer and covering a top of the first plated layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1 to 6 are sectional views sequentially illustrating a method of forming a semiconductor device, according to a first embodiment of the present invention; and

FIGS. 7 to 10 are sectional views sequentially illustrating a method of forming a semiconductor device, according to a second embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

In the specification, when it is mentioned that a certain material layer such as a conductive layer, a semiconductor layer, or an insulation layer is disposed “on” another material or a substrate, the certain material layer may be directly formed on the another material layer or the substrate, or another material layer may be interposed therebetween. Also, though terms like a first, a second, and a third are used to describe a material layer and an operation in various embodiments of the inventive concept, they are merely used to distinguish a specific material layer or operation from other material layers or operations and thus are not limited to these terms.

In the following description, the technical terms are used only for explaining a specific exemplary embodiment while not limiting the inventive concept. The terms of a singular form may include plural forms unless referred to the contrary. The meaning of ‘comprises’ and/or ‘comprising’ specifies a property, a region, a fixed number, a step, a process, an element and/or a component, but does not exclude other properties, regions, fixed numbers, steps, processes, elements and/or components.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a semiconductor package region. Thus, this should not be construed as limited to the scope of the present invention.

Hereinafter, a nonvolatile memory device according to embodiments of the inventive concept will be described in more detail with reference to the drawings. In embodiments of the present invention, a via may correspond to a silicon through via.

### First Embodiment

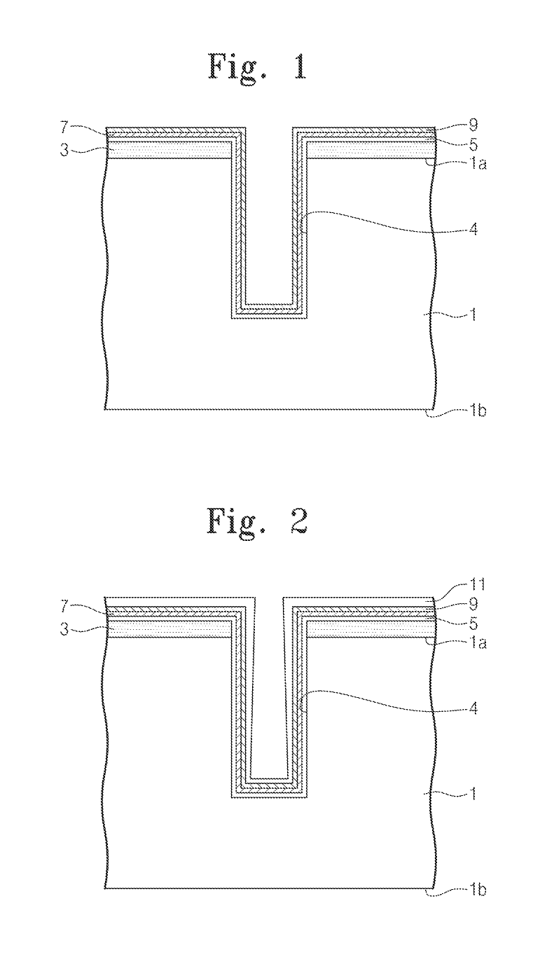

FIGS. 1 to 6 are sectional views sequentially illustrating a method of forming a semiconductor device, according to a first embodiment of the present invention.

Referring to FIG. 1, a substrate 1 having an upper surface 1a and a lower surface 1b is provided. A buffer layer 3 is formed on the upper surface 1a of the substrate 1. The substrate 1, for example, may be a semiconductor substrate such as a silicon substrate. The buffer layer 3 may be a silicon oxide layer. Although not shown, a transistor, a resistor, an interconnection and an interlayer dielectric may be formed on the substrate 1 before forming the buffer layer 3. A via hole 4 is formed by removing a portion of the buffer layer 3 and substrate 1. The via hole 4 may be formed in a photolithography process and/or an etching process, or formed with a laser. The via hole 4 may be formed not to expose the lower surface 1b of the substrate 1. A dielectric liner 5 is conformally formed on the substrate 1 where the via hole 4 is formed. The dielectric liner 5 may include silicon oxide and/or silicon nitride. A barrier layer 7 may be conformally formed on the substrate 1 where the dielectric liner 5 is formed. The barrier layer 7 can prevent the diffusion or electromigration of a metal forming a via. The barrier layer 7 may include at least one that is selected from the group consisting of titanium, titanium nitride, tantalum, and tantalum nitride. A seed layer 9 is conformally formed on the barrier layer 7. The seed layer 9 may be formed in a Chemical Vapor Deposition (CVD) process or an Atomic Layer Deposition (ALD) process having good step coverage characteristic. The seed layer 9, for example, may be formed of copper.

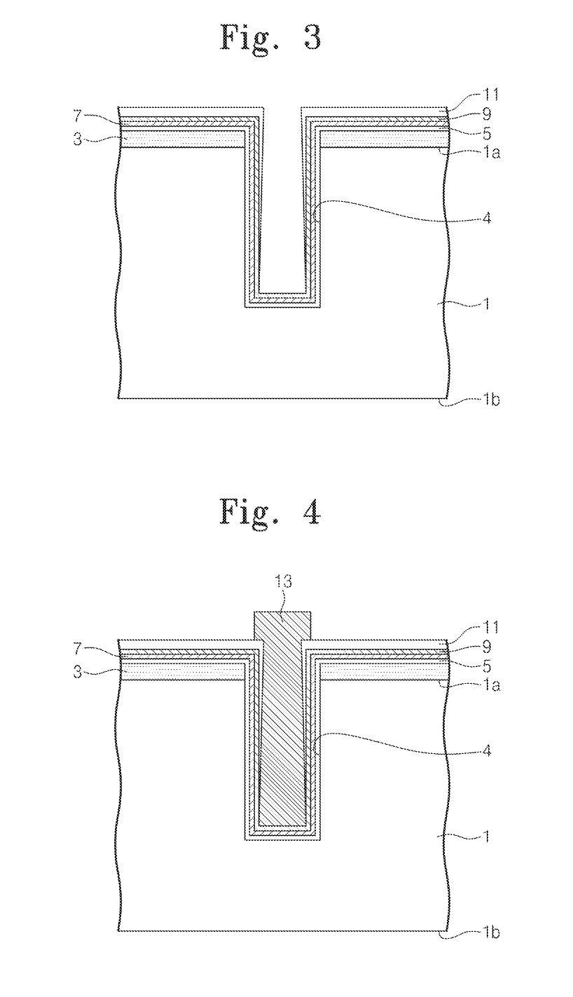

Referring to FIGS. 2 and 3, an unseeded layer 11 incapable of serving as a seed is formed by a process having bad step coverage characteristic. For example, at least one that is selected from the group consisting of a PVD process, a plasma-enhanced chemical vapor deposition process, a sputtering process, and a spin coating process may be used as the process having bad step coverage characteristic. The unseeded layer 11 may be thickly formed on the seed layer 9 disposed on the substrate 1 and thinly formed toward inside the via hole 4, through the process having bad step coverage characteristic.

When the seed layer 9 disposed at the bottom of the via hole 4 is covered by the unseeded layer 11 as in FIG. 2, by performing a wet etching or dry etching process, as illustrated in FIG. 3, the unseeded layer 11 is removed from the bottom of the via hole 4, and thus, the seed layer 9 is exposed.

Alternatively, as illustrated in FIG. 3, due to the process having bad step coverage characteristic, the unseeded layer 11 may not be formed on the seed layer 9 disposed at the bottom of the via hole 4. In this case, a wet etching or dry etching process for removing the unseeded layer 11 from the bottom of the via hole 4 may not be performed.

Therefore, as illustrated in FIG. 3, the unseeded layer 11 covers the seed layer 9 disposed on the substrate 1 and the seed layer 9 disposed at a side wall of the via hole 4, in which case the seed layer 9 disposed at the bottom of the via hole 4 is exposed.

Referring to FIG. 4, by performing an plating process, a plated layer 13 is grown upward from the seed layer 9 that is exposed at the bottom of the via hole 4, thereby filling the via hole 4. The plating process may be an electroplating process. The plated layer 13, for example, may be formed of copper. The plated layer 13 may be formed higher than a top of the buffer layer 3. The plated layer 13 is not grown on a surface of the unseeded layer 11. Accordingly, the plated layer 13 may be formed upward from the seed layer 9 without a void being formed.

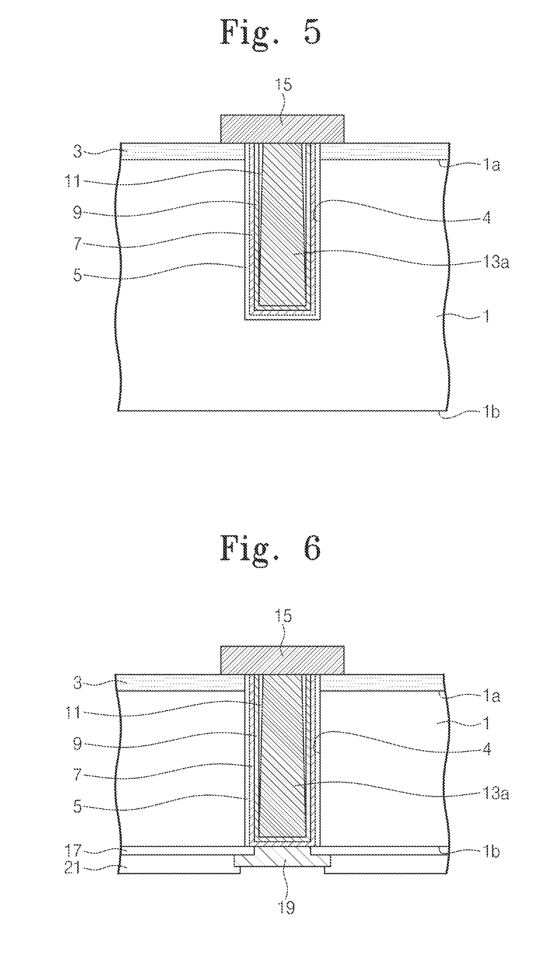

Referring to FIG. 5, by performing a planarization etching process, the dielectric liner 5, the barrier layer 7, the seed layer 9, the unseeded layer 11, and the plated layer 13 are removed from on the buffer layer 3, and the top of the buffer layer 3 is exposed. Accordingly, a via 13a including the plated layer 13 may be formed in the via hole 4. Furthermore, a first bonding pad 15 overlapped with the via 13a is formed.

Referring to FIG. 6, by performing a grinding process, the substrate 1 under the via hole 4 is removed to expose a bottom of the barrier layer 7. Alternatively, a bottom of the seed layer 9 or a bottom of the via 13a may be exposed by the grinding process. A first passivation layer 17 covering the bottom 1b of the substrate 1 is formed. The first passivation layer 17 may be formed of silicon nitride. The first passivation layer 17 is formed to expose the bottom of the barrier layer 7. A second bonding pad 19 contacting the bottom of the barrier layer 7 is formed. Furthermore, a second passivation layer 21 that covers the first passivation layer 17 and exposes the second bonding pad 19 may be formed at the bottom 1b of the substrate 1.

In a semiconductor device of FIG. 6 formed by the above-described method, a buffer layer 3 is disposed on the top 1a of the substrate 1, which includes the top 1 and the bottom 1b. The via 13a may pass through the buffer layer 3 and the substrate 1. A seed layer 9 is disposed between the via 13a and the substrate 1. An unseeded layer 11 is disposed between the seed layer 9 and the via 13a. A barrier layer 7 is disposed between the seed layer 9 and the substrate 1, and a dielectric liner 5 is disposed between the barrier layer 7 and the substrate 1. A first bonding pad 15 overlapped with the via 13a is disposed on the top 1a. First and second passivation layers 17 and 21 are disposed at the bottom 1b, and a second bonding pad 19 is disposed to electrically connected to the via 13a.

### Second Embodiment

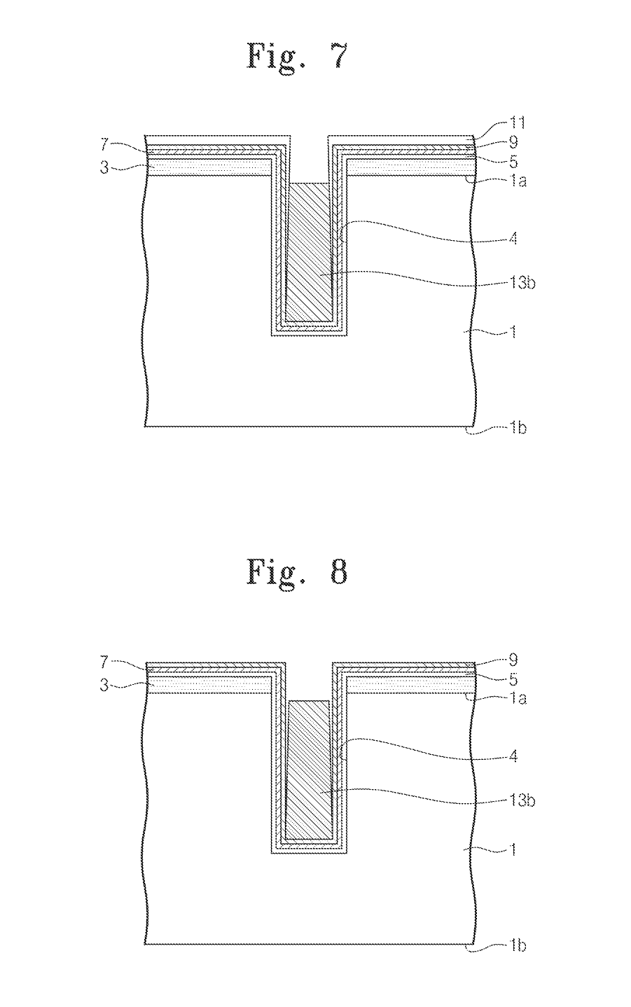

FIGS. 7 to 10 are sectional views sequentially illustrating a method of forming a semiconductor device, according to a second embodiment of the present invention.

Referring to FIG. 7, an unseeded layer 11 is formed as in FIG. 3, and thereafter, a first plated layer 13b is grown upward from a seed layer 9 that is exposed at a bottom of the via hole 4, in a first plating process. When the first plated layer 13b fills a large portion of the via hole 4 and is lower in height than a top of the unseeded layer 11, the first plating process is stopped.

Referring to FIG. 8, the unseeded layer 11 is removed. The unseeded layer 11 may be removed by an isotropic etching process. By removing the unseeded layer 11, a top and side wall of the seed layer 9 and a side wall of the first plated layer 13b are exposed.

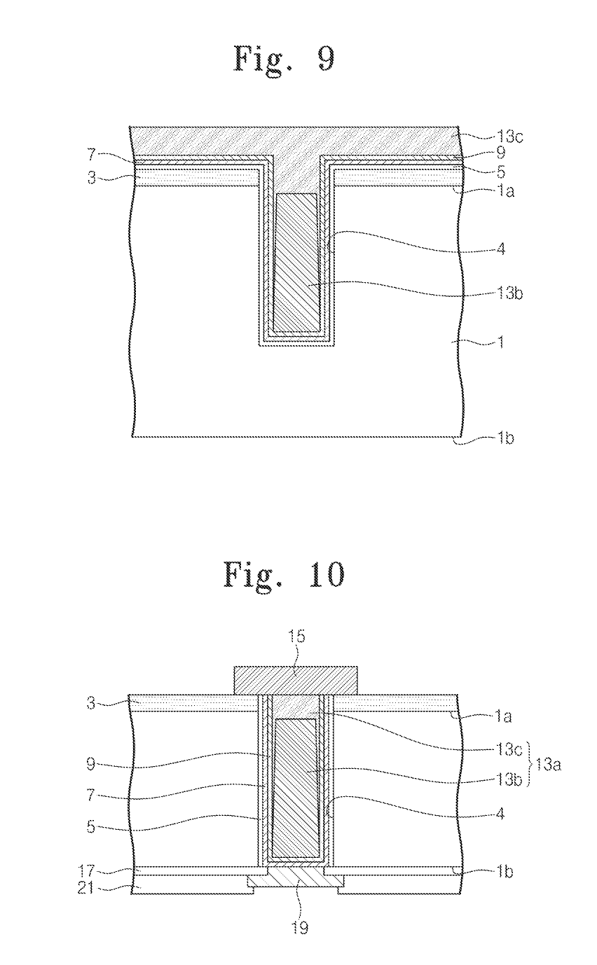

Referring to FIG. 9, a second plated layer 13c is grown from a top and side wall of the first plated layer 13b and the top and side wall of the seed layer 9 in a second plating process. Therefore, the second plated layer 13c may be formed to cover the substrate 1. The seed layer 9, the first plated layer 13b and the second plated layer 13c may be formed of copper.

Referring to FIG. 10, by performing a planarization etching process, the dielectric liner 5, the barrier layer 7, the seed layer 9, the unseeded layer 11, and the second plated layer 13c on the buffer layer 3 are removed, and the top of the buffer layer 3 is exposed. Accordingly, a via 13a including the first and second plated layers 13a and 13b may be formed in the via hole 4. Furthermore, a first bonding pad 15 overlapped with the via 13a is formed. By performing a grinding process, the substrate 1 under the via hole 4 is removed to expose a bottom of the barrier layer 7. Alternatively, a bottom of the seed layer 9 or a bottom of the via 13a may be exposed by the grinding process. A first passivation layer 17 covering the bottom 1b of the substrate 1 is formed. The first passivation layer 17 may be formed of silicon nitride. The first passivation layer 17 is formed to expose the bottom of the barrier layer 7. A second bonding pad 19 contacting the bottom of the barrier layer 7 is formed. Furthermore, a second passivation layer 21 that covers the first passivation layer 17 and exposes the second bonding pad 19 may be formed at the bottom 1b of the substrate 1.

In a semiconductor device of FIG. 10, the unseeded layer 11 is not formed. The via 13a includes the first and second plated layers 13a and 13b. The second plated layer 13c contacts the seed layer 9. Except such elements, the semiconductor device according to the second embodiment of the present invention is the same as the semiconductor device according to the first embodiment of the present invention.

In the method of forming the semiconductor device, according to the embodiments of the present invention, by forming the unseeded layer that covers the seed layer disposed on the substrate and at the side wall of the via hole, exposes the seed layer disposed at the bottom of the via hole, and cannot serve as a seed, the plated layer configuring the via is formed upward from the seed layer in a bottom-up growth process, and thus, a void is not formed. Also, the inlet of the via hole is not blocked by using the bottom-up growth process, and thus, an electroplating speed can increase, thereby shortening a time taken in filling the via hole with a metal.

Moreover, the via formed by the above-described method, according to the embodiments of the present invention, does not include a void, and thus, a semiconductor device with enhanced reliability can be provided.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of forming a semiconductor device, the method comprising:
forming a via hole in a substrate;
forming a seed layer at least on a bottom and side wall of the via hole and the substrate;
forming an unseeded layer which covers the seed layer disposed at the side wall of the via hole, exposes the seed layer disposed at the bottom of the via hole, and does not serve as a seed; and
growing a plated layer from the exposed seed layer to fill the via hole by performing a plating process.

2. The method of claim 1, wherein the unseeded layer comprises at least one selected from a group which comprises silicon oxide, silicon nitride, silicon, titanium, titanium nitride, titanium tungsten, tungsten, tantalum, tantalum nitride, and aluminum.

3. The method of claim 1, wherein the seed layer and the plated layer comprises copper.

4. The method of claim 1, wherein the forming of an unseeded layer uses at least one selected from a group which comprises a physical vapor deposition process, a plasma-enhanced chemical vapor deposition process, a sputtering process, and a spin coating process.

5. The method of claim 1, wherein the forming of an unseeded layer comprises:
forming an unseeded layer which thickly covers the seed layer disposed at the side wall of the via hole and thinly covers the seed layer disposed at the bottom of the via hole; and
removing the unseeded layer disposed at the bottom of the via hole to expose the seed layer.

6. The method of claim 1, wherein,
the plated layer comprises first and second plated layers, and
the forming of a via hole comprises:
growing the first plated layer from the seed layer to a height lower than a top of the unseeded layer;
removing the unseeded layer; and
growing the second plated layer from the seed layer and the first plated layer.

7. The method of claim 1, further comprising planarly removing the seed layer, the unseeded layer and the plated layer on the substrate to expose the substrate.

8. The method of claim 1, further comprising:
before the forming of a seed layer,
forming an insulation layer conformally covering the substrate where the via hole is formed; and
forming a barrier layer covering the insulation layer.

9. A semiconductor device comprising:
a substrate;
a via formed in the substrate;
a seed layer disposed between the substrate and the via; and
an unseeded layer disposed between the seed layer and the via, wherein the unseeded layer does not function as a seed.

10. The method of claim 9, wherein the unseeded layer comprises at least one selected from a group which comprises silicon oxide, silicon nitride, silicon, titanium, titanium nitride, titanium tungsten, tungsten, tantalum, tantalum nitride, and aluminum.

11. A semiconductor device comprising:
a substrate;
a via formed in the substrate; and
a seed layer disposed between the substrate and the via,
wherein the via comprises:
a first plated layer having a top which is disposed at a height lower than a top of the substrate, and not contacting a top of the seed layer; and
a second plated layer disposed on the first plated layer, and contacting an upper side wall of the first plated layer and covering a top of the first plated layer.
